(19) United States
(12) Patent Application Publication
(10) Pub. No.: US 2024/0170445 A1
(43) Pub. Date: May 23, 2024

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventors: Juno Kim, Suwon-si (KR); Minwoo Rhee, Suwon-si (KR); Ilyoung Han, Suwon-si (KR); Juhyung Lee, Suwon-si (KR); Kyeongbin Lim, Suwon-si (KR)

(73) Assignee: SAMSUNG ELECTRONICS CO., LTD., Suwon-si (KR)

(21) Appl. No.: 18/379,956

(22) Filed: Oct. 13, 2023

(30) Foreign Application Priority Data
Nov. 23, 2022 (KR) 10-2022-0158011

(51) Int. Cl. H01L 23/00; H01L 21/66

(52) U.S. Cl. CPC H01L 24/80; H01L 22/12; H01L 2224/80224; H01L 2224/8023; H01L 2224/80895; H01L 2224/80896; H01L 2224/80908

(57) ABSTRACT

Provided is a method of manufacturing a semiconductor package, the method including: providing a first semiconductor die on a stage; bonding a second semiconductor die to the first semiconductor die to each other; applying heat to a surface of the second semiconductor die, which is opposite to a bonding interface of the first semiconductor die and the second semiconductor die; and measuring a temperature change on the surface of the second semiconductor die to which the heat is applied to inspect a state of the bonding interface.

### CROSS-REFERENCE TO RELATED APPLICATION

This application claims priority under 35 U.S.C. 119 to Korean Patent Application No. 10-2022-0158011, filed on Nov. 23, 2022 in the Korean Intellectual Property Office, the disclosure of which is incorporated herein in its entirety by reference.

### BACKGROUND

### 1. Field

Embodiments of the disclosure relate to a semiconductor package and a method of manufacturing the semiconductor package. More particularly, the embodiments relate to an apparatus for inspecting defects in a semiconductor package including a plurality of chips stacked by a hybrid bonding process and a method of manufacturing the semiconductor package using the same.

### 2. Description of Related Art

In order to manufacture a multi-chip package in which at least two semiconductor chips are stacked, dies may be bonded on a wafer by performing a die to wafer bonding process. At this time, a defect such as a void may occur at a bonding interface between the die and the wafer and/or a bonding interface between the dies. In related arts, scanning acoustic tomography (SAT) may be used to inspect voids at bonding interfaces of stacked semiconductor dies. However, in the case of SAT, since a die stack, which is a sample, is placed inside a liquid, and then, presence or absence of voids is checked, water adsorbed on a die surface after the test may cause additional voids during a subsequent annealing process, or SAT can be applied only after the semiconductor die stacking is completed.

### SUMMARY

Embodiments of the disclosure provide a defect inspection apparatus for a semiconductor package that is able to improve a process yield when stacking semiconductor dies by a hybrid bonding process.

The embodiments provide a method of manufacturing a semiconductor package using the defect inspection apparatus.

According to embodiments, there is provided a defect inspection apparatus for a semiconductor package, which may include: a stage configured to support a die stack comprising a second semiconductor die bonded to a first semiconductor die; a heater configured to apply heat to a surface of the second semiconductor die on the stage, which is opposite to a bonding interface of the first semiconductor die and the second semiconductor die; and a camera configured to measure a temperature change on the surface of the second semiconductor die to which the heat is applied to check a state of the bonding interface.

According to embodiments, there is provided a method of manufacturing a semiconductor package using the defect inspection apparatus. The method may include: providing a first semiconductor die on a stage; bonding a second semiconductor die to the first semiconductor die to each other; applying heat to a surface of the second semiconductor die, which is opposite to a bonding interface of the first semiconductor die and the second semiconductor die; and measuring a temperature change on the surface of the second semiconductor die to which the heat is applied to inspect a state of the bonding interface.

According to embodiments, the inspecting the state of the bonding interface may include determining whether a void exists between the first semiconductor die and the second semiconductor die by the measuring the temperature change.

According to embodiments, there is provided a method of manufacturing a semiconductor package using the defect inspection apparatus. The method may include: placing a buffer die on a stage; sequentially bonding a plurality of semiconductor dies on the buffer die; and inspecting a state of a bonding interface of each of the bonded semiconductor dies when each of the semiconductor dies is bonded to another of the bonded semiconductor dies, wherein inspecting the state of the bonding interface comprises: applying heat to a surface of each of the bonded semiconductor dies, which is opposite to the bonding interface thereof; and detecting an infrared ray emitted from the surface of each of the bonded semiconductor dies to which the heat is applied to determine the state of the bonding interface.

According to embodiments, in the defect inspection apparatus, the heater is configured to irradiate a light forming a line-shaped irradiation area extending in a first direction on the surface of the second semiconductor die, and the camera including a thermal imaging camera is configured to generate a thermal image by detecting an infrared ray emitted from the surface of the second semiconductor die.

Since the defect inspection apparatus observes the temperature change on the surface of the second semiconductor die, which is locally heated by the heater including a heat source, using the thermal image camera, it may be possible to prevent deterioration of the semiconductor dies by inspecting the state of the bonding interface including where voids are present in the bonding interface without a separate medium such as water that is used in case of an ultrasonic inspection system (SAT). Further, high inspection speed may be implemented by utilizing thermal response, and a process yield may be improved by performing all inspections in-situ after each die bonding process.

Moreover, the defect inspection apparatus may be used not only in a die to wafer bonding process, but also in a wafer to wafer bonding process to inspect defects inside a sealing member such as an epoxy molding compound.

### BRIEF DESCRIPTION OF DRAWINGS

The embodiments will be more clearly understood from the following detailed description taken in conjunction with the accompanying drawings. FIGS. 1 to 17 represent non-limiting, embodiments as described herein.

FIG. 1 is a perspective view illustrating a defect inspection apparatus for a semiconductor package, in accordance with embodiments.

FIG. 2 is a plan view illustrating a semiconductor die stack that is locally heated by a heater in FIG. 1, in accordance with embodiments.

FIG. 3 is a cross-sectional view taken along the line I-I′ in FIG. 2, in accordance with embodiments.

FIG. 4 represents a thermal image obtained by a thermal imaging camera capturing a portion ‘A’ of FIG. 2, and a graph illustrating temperature distribution across a specific area of a thermal image, in accordance with embodiments.

FIGS. 5A to 5C are cross-sectional views illustrating reciprocating movement of a stage of FIG. 1 for applying heat in the form of a sinusoidal wave, in accordance with embodiments.

FIG. 6 is a graph showing a difference in die surface temperature according to presence or absence of a void in a region of interest obtained according to the heating method of FIGS. 5A to 5C, in accordance with embodiments.

FIG. 7 is a diagram illustrating a method of stacking semiconductor dies, in accordance with embodiments.

FIGS. 8 to 17 are views illustrating a method of manufacturing a semiconductor package, in accordance with embodiments.

### DETAILED DESCRIPTION

Hereinafter, the embodiments of the disclosure will be explained in detail with reference to the accompanying drawings. All of these embodiments are example embodiments, and thus, the disclosure is not limited thereto and may be realized in various other forms.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Spatially relative terms, such as “over,” “above,” “on,” “upper,” “below,” “under,” “beneath,” “lower,” “left,” “right,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

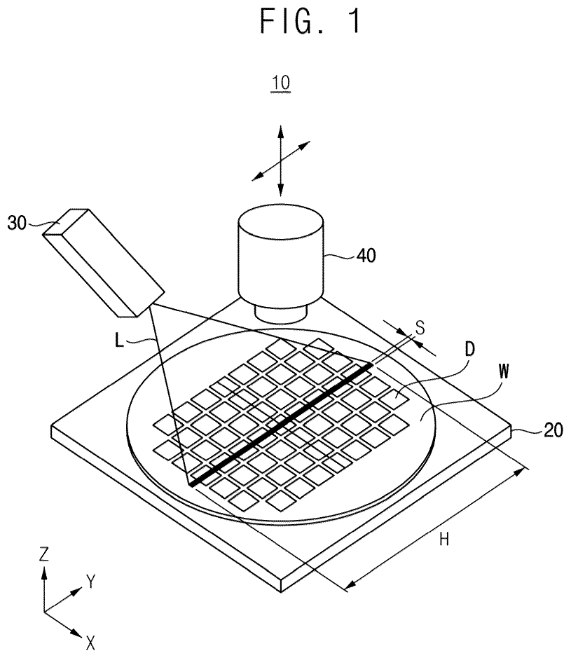

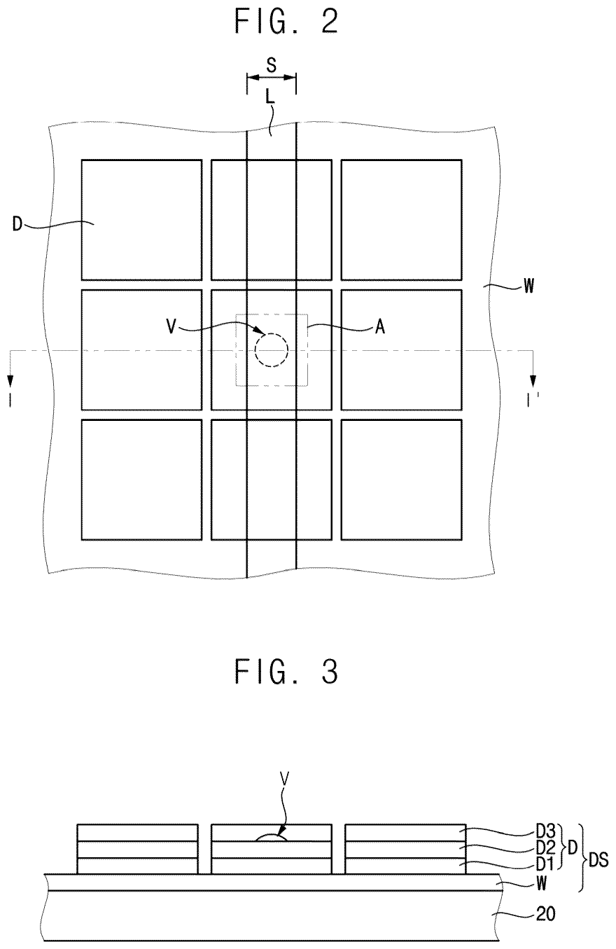

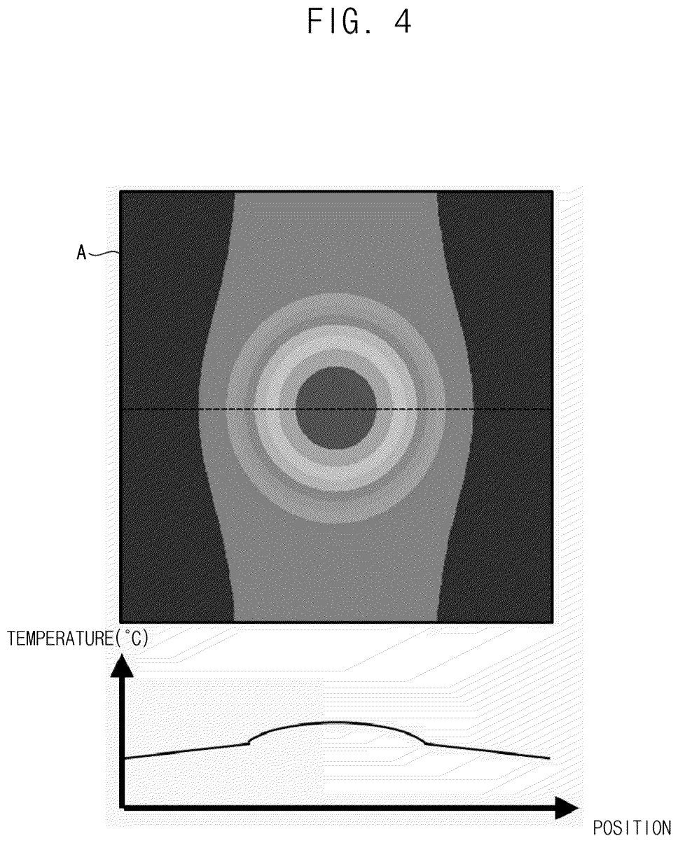

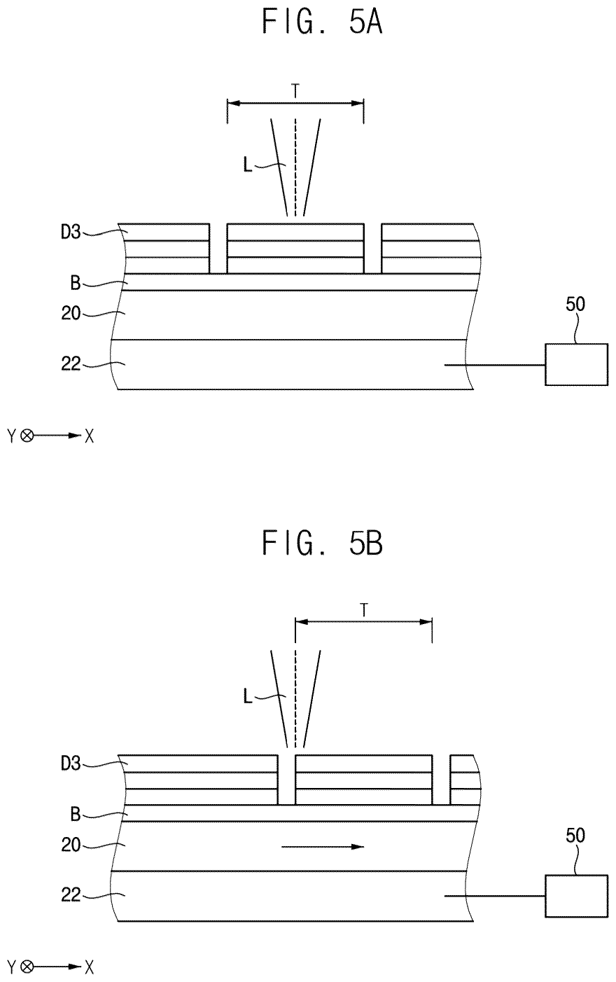

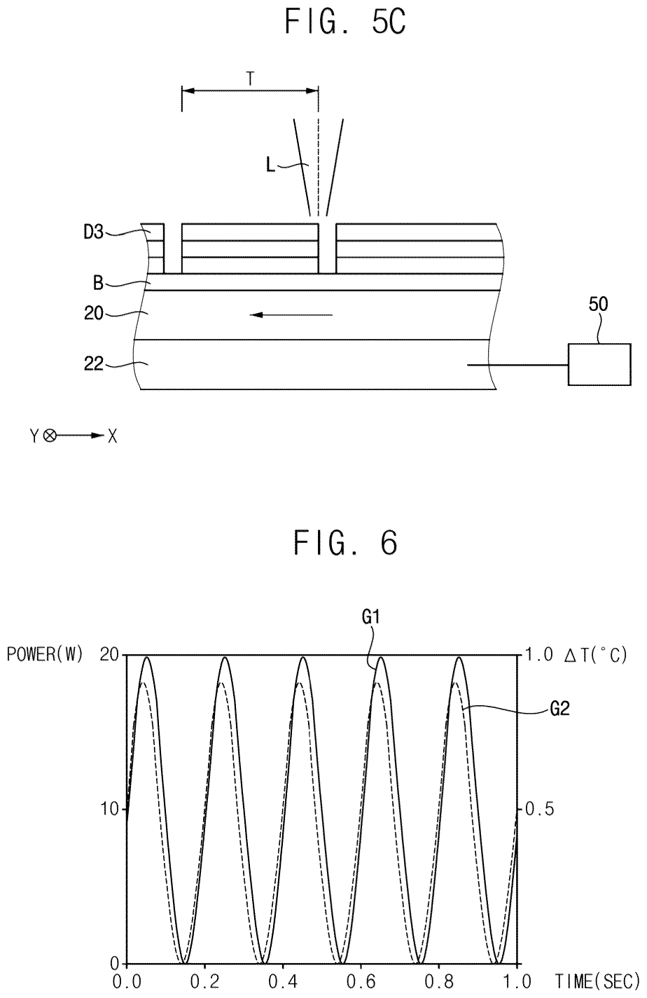

FIG. 1 is a perspective view illustrating a defect inspection apparatus for a semiconductor package, in accordance with embodiments. FIG. 2 is a plan view illustrating a semiconductor die stack that is locally heated by a heater in FIG. 1, in accordance with embodiments. FIG. 3 is a cross-sectional view taken along the line I-I′ in FIG. 2, in accordance with embodiments. FIG. 4 represents a thermal image obtained by a thermal imaging camera capturing a portion ‘A’ of FIG. 2, and a graph illustrating temperature distribution across a specific area of the thermal image, in accordance with embodiments. FIGS. 5A to 5C are cross-sectional views illustrating reciprocating movement of a stage of FIG. 1 for applying heat in the form of a sinusoidal wave, in accordance with embodiments. FIG. 6 is a graph showing a difference in die surface temperature according to presence or absence of a void in a region of interest obtained according to the heating method of FIGS. 5A to 5C, in accordance with embodiments.

Referring to FIGS. 1 to 6, a defect inspection apparatus for a semiconductor package 10 may include a stage 20, a heater 30 and a camera 40. In addition, the defect inspection apparatus 10 may further include a controller 50 connected to the stage 20, the heater 30 and the camera 40 to control their operations.

In example embodiments, the defect inspection apparatus 10 may be a monitoring apparatus for detecting a void at a bonding interface of dies that are bonded to each other by a semiconductor die stacking process. For example, the defect inspection apparatus 10 may inspect, in-situ, a void at a bonding interface of semiconductor dies bonded to each other through a die to wafer hybrid bonding process. Additionally, the defect inspection apparatus 10 may be used to inspect a void inside a molding member such as an epoxy molding compound (EMC) in a semiconductor package or a void inside an adhesive film in dies bonded to each other by the adhesive film. Herein, a bonding interface of semiconductor dies refer to an interface between the semiconductor dies when these dies are bonded to each other.

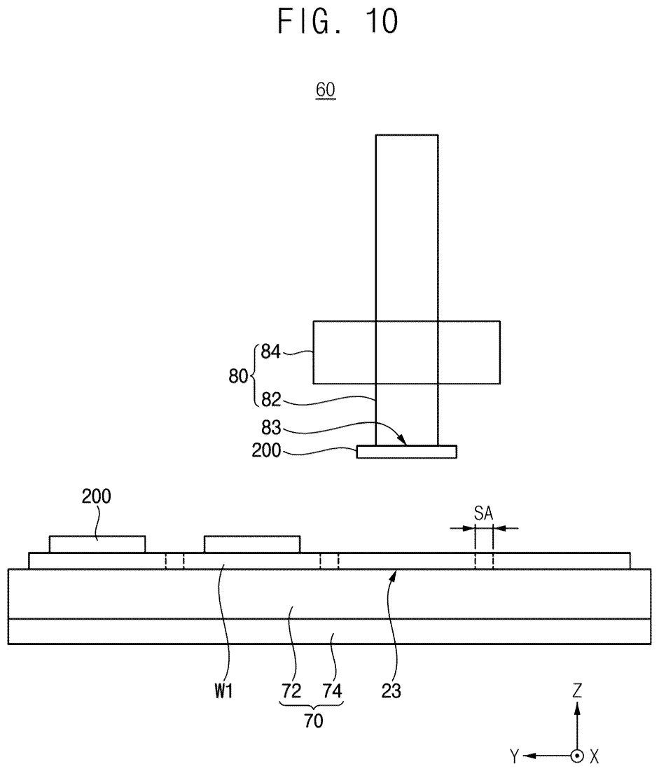

As illustrated in FIG. 1, the stage 20 may support a die stack DS (see, e.g., FIG. 3) including a semiconductor die D and a wafer W bonded to each other. For example, a die bonding apparatus 60 (see FIG. 10) may pick up and bond the semiconductor die D which may be a stack of a plurality of semiconductor dies on the wafer W, and then, the wafer W including the semiconductor die D bonded thereon may be loaded on the stage 20 of the defect inspection apparatus 10 to perform a defect inspection process.

The stage 20 may be disposed to be movable in at least one direction. A stage driver 22 may move the stage 20 in an X direction and a Y direction according to a control signal from the controller 50. The moving speed of the stage 20 may be adjustable. As will be described later, the stage 20 may reciprocally move within a preset distance T based on a specific position.

In example embodiments, the heater 30 may apply local heat to an upper surface of the semiconductor die D on the stage 20. The heater 30 may include a heat source such as a laser or a halogen lamp to apply the local heat. The heat source of the heater 30 may radiate a light L forming a line-shaped radiation area extending in a first direction (Y direction) on the upper surface of the semiconductor die D. The first direction may be a direction perpendicular to the moving direction of the stage 20. The heat source may generate the light having a predetermined wavelength. The upper surface of the semiconductor die D may refer to a top surface opposite to a bottom surface of the semiconductor die D which is a bonding interface formed between the semiconductor die D and the wafer W therebelow.

For example, the heater 30 may include a halogen line heater. The halogen line heater may heat a local area by condensing a light in a line shape. A width (S) of the line-shaped irradiation area of the light L irradiated from the heat source may be a similar value to a size of a void, and a length (H) of the line-shaped irradiation area may be a similar value to a diameter of the wafer. The power and frequency of the heat source may be adjusted in consideration of the sizes of the semiconductor dies, a void to be inspected, etc.

The camera 40 may measure a temperature change on the upper surface of the semiconductor die D to which the local heat is applied, and may detect the presence or absence of a gap at a bonding interface of the semiconductor die D. The camera 40 may include a thermal imaging camera. The thermal imaging camera may generate a thermal image by detecting infrared rays emitted from the upper surface of the semiconductor die D. The camera 40 may be disposed above the stage 20 to be movable in the X direction or the Y direction. In addition, the camera 40 may be disposed to be movable in a Z direction above the stage 20.

Referring to FIG. 3, the semiconductor die D may include a plurality of semiconductor dies D1, D2 and D3 stacked in this order on the wafer W. The semiconductor die D may include a void V formed at a bonding interface of an upper semiconductor die D3 and a lower semiconductor die D2 which may have a diameter of 10 μm to 1,000 μm. The specifications of the thermal imaging camera may be determined according to the size of a void to be inspected. When the temperature resolution (NETD: Noise Equivalent Temperature Difference) of the thermal imaging camera is 40 mK and the spatial resolution is 25 μm/pixel, the thermal imaging camera may inspect small voids of 100 μm or less.

As illustrated in FIGS. 3 and 4, after bonding the upper semiconductor die D3 to the lower semiconductor die D2 by performing each stacking step (e.g., three-layer stacking step), heat may be applied to the upper surface of the upper semiconductor die D3 through the heat source of the heater 30, and the upper surface of the upper semiconductor die D3 may be observed through the thermal imaging camera, to obtain a thermal image representing temperature distribution of upper surface of the upper semiconductor die D3 according to the presence or absence of voids, i.e., air gaps.

Heat radiated from the heat source onto the upper surface of the upper semiconductor die D3 may diffuse in a depth direction of the die stack DS. In the process of heat diffusion, a heat transfer path may vary according to the presence or absence of a void at the bonding interface formed in the stacking step. This is because the thermal diffusivity at the void is relatively small compared to the thermal diffusivity at a completely bonded interface. Thus, heat may spread (diffuse) not in a direction where the void exists but bypasses the void. For example, thermal diffusivity of silicon is 0.895 [cm²/s], and thermal diffusivity of air is 0.213 [cm²/s]. If a thickness of bonded semiconductor dies is sufficiently thin, a temperature singularity may occur on a surface of the upper semiconductor die D3 irradiated with heat due to the change in the heat transfer path around the void. Accordingly, while the stage 20 moves, the thermal imaging camera may measure a temperature change of the surface of the upper semiconductor die within a region of interest (ROI), and thus, it may be possible to inspect whether a void is generated at the bonding interface in the previous bonding process.

In example embodiments, the defect inspection apparatus 10 may apply heat in the form of a sinusoidal wave to the upper surface of the upper semiconductor die D3 on the lower semiconductor die D2. As shown in FIGS. 5A to 5C, while the stage 20 reciprocally moves within a preset distance based on a specific position, the heater 30 over the stage 20 may irradiate a light (L) to a specific position on the upper surface of the upper semiconductor die D3. For example, the specific position may be a virtual line passing through a center of the upper semiconductor die D3 in a direction parallel to the Y direction, and the preset distance may be a distance T of a portion of the upper semiconductor die D3.

Referring to FIG. 6, a graph G1 in a solid-line curve shows heat (power (W)) in the form of a sinusoidal wave applied to both a first upper semiconductor die without a void in a bonding interface of a lower semiconductor die therebelow and a second upper semiconductor die with a void in a bonding surface of a lower semiconductor die therebelow, and a graph G2 in a dashed-line curve is a surface temperature difference (ΔT, ° C.) between a surface temperature (T #1) of the first upper semiconductor die and a surface temperature (T #2) of the second upper semiconductor die in a region of interest (ROI). The temperature difference (ΔT) may be a difference value between a temperature (T #1) in the die without a void and a temperature (T #2) in the die with a void. For example, several semiconductor dies D may be positioned within the region of interest (ROI), and there may be some dies with voids and other dies without voids within the region of interest (ROI). Compared to the die without a void, the die with voids does not spread heat well due to the thermal resistance of the voids, so the temperature (T #2) in the die with a void may increase, which is different from the temperature (T #1) of the die without a void. In other words, the larger the temperature difference, the easier the IR Camera can detect the die with voids. As the stage 20 periodically moves from side to side, the temperature difference appearing on the surface of the upper semiconductor dies shows a specific cycle because the heat source entering vicinity of the void does not reach a steady state and is in a transient state. At this time, if a position where the temperature difference is the largest is extracted, void inspection can be effectively performed.

As mentioned above, the defect inspection apparatus 10 for the semiconductor package may include the stage 20 configured to support the die stack DS including the semiconductor die D bonded on the wafer W, the heater 30 configured to apply local heat to the upper surface of the upper semiconductor die D, and the camera 40 configured to measure the temperature change on the upper surface of the semiconductor die D to which the local heat is applied and check the presence or absence of the void V at the bonding interface of the upper semiconductor die D.

Since the defect inspection apparatus 10 observes the temperature change on the surface of the semiconductor die D, which is locally heated by the heat source, with the thermal image camera, it may be possible to prevent deterioration of the semiconductor die D by inspecting the presence or absence of voids without a separate medium such as water that is used in the case of an ultrasonic inspection system (SAT). Further, high inspection speed may be implemented by utilizing a thermal response, and process yield may be improved by performing all inspections in-situ after each die bonding process.

Moreover, the defect inspection apparatus 10 may be used not only in a die to wafer bonding process, but also in a wafer to wafer bonding process to inspect defects inside a sealing member such as epoxy molding compound. Further, the defect inspection apparatus 10 detecting the temperature change may also be used to detect a state of an interface between semiconductor dies other than detecting voids. For example, the defect inspecting apparatus 10 may detect presence of a defect, abnormality, or presence of an external material, not being limited thereto, in the interface of the semiconductor dies other than presence of a void described above.

Hereinafter, a method of stacking semiconductor dies using the defect inspection apparatus of FIG. 1 will be described.

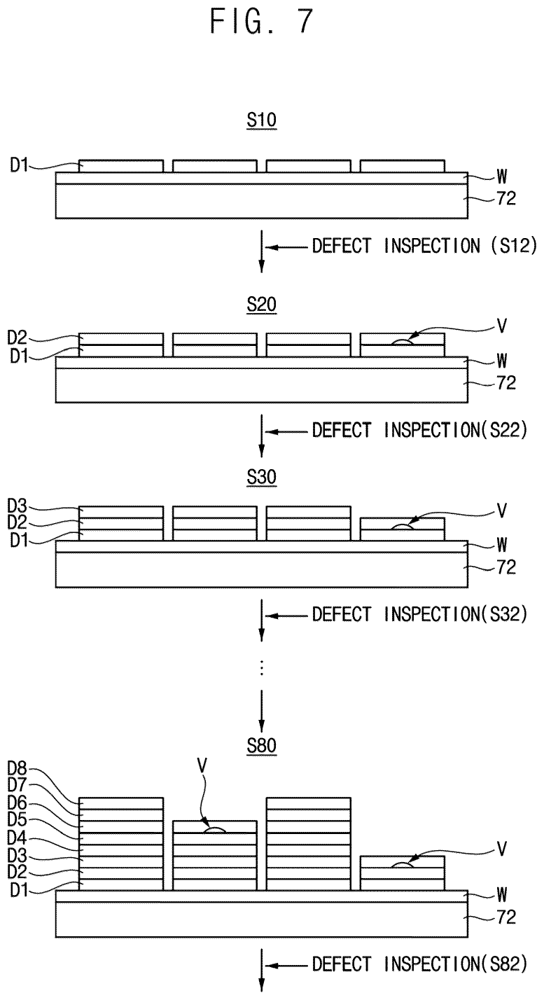

FIG. 7 is a diagram illustrating a method of stacking semiconductor dies, in accordance with embodiments.

Referring to FIGS. 1 and 7, first semiconductor dies D1 may be bonded on a wafer W (S10), and presence or absence of voids at bonding interfaces of the first semiconductor dies D1 and the wafer W may be inspected (S12).

In embodiments, the wafer W in which a plurality of buffer dies are formed may be loaded onto a first stage 72 of the die bonding apparatus 60 (see FIG. 10). The die bonding apparatus 60 may pick up the first semiconductor dies D1 separated by a sawing process, and may bond them onto a buffer die of the wafer W.

Then, the wafer W to which the first semiconductor dies D1 are bonded may be loaded onto the stage 20 of the defect inspection apparatus 10 of FIG. 1, and presence or absence of voids at the bonding interfaces of the first semiconductor dies D1 and the wafer W may be inspected. Through the defect inspection, good first semiconductor dies D1 (KGD, Known Good Die) having no voids may be selected.

Then, second semiconductor dies D2 may be bonded onto the wafer W to which the first semiconductor dies D1 are bonded (S20), and presence or absence of voids at bonding interfaces of the second semiconductor dies D2 and the first semiconductor dies D1 may be inspected (S22).

In embodiments, the wafer W to which the first semiconductor dies D1 are bonded may be loaded onto the first stage 72 of the die bonding apparatus 60, and the die bonding apparatus 60 may pick up the second semiconductor dies D2 separated by a sawing process, and may bond them onto the good first semiconductor dies D1.

Then, the wafer W to which the second semiconductor dies D2 are bonded may be loaded onto the stage 20 of the defect inspection apparatus 10 of FIG. 1, and presence or absence of voids at the bonding interfaces of the second semiconductor dies D2 and the first semiconductor dies D1 may be inspected. Through the defect inspection, good second semiconductor dies D2 KGD having no voids may be selected.

Then, third semiconductor dies D3 may be bonded on the wafer W (S30) to which the first semiconductor die D1 and the second semiconductor die D2 are bonded, and presence or absence of voids at bonding interfaces of the third semiconductor dies D3 and the second semiconductor dies D2 may be inspected (S32).

In embodiments, the wafer W to which the second semiconductor dies D2 are bonded may be loaded onto the first stage 72 of the die bonding apparatus 60, and the die bonding apparatus 60 may pick up the third semiconductor dies D3 separated by a sawing process, and may bond them onto the good second semiconductor dies D2.

Then, the wafer W to which the third semiconductor dies D3 are bonded may be loaded onto the stage 20 of the defect inspection apparatus 10 of FIG. 1, and presence or absence of voids at the bonding interfaces of the third semiconductor dies D3 and the second semiconductor dies D2 may be inspected. Through the defect inspection, good third semiconductor dies D3 KGD having no voids may be selected.

Then, the bonding step and the defect inspection step may be repeatedly performed to bond fourth to seventh semiconductor dies D4, D5 and D7 on the wafer W respectively (S30), and after each of the bonding steps, the defect inspection step may be performed.

Then, eighth semiconductor dies D8 may be bonded on the wafer W (S80) to which the first to seventh semiconductor dies D1-D7, and presence or absence of voids at bonding interfaces of the bonded eighth semiconductor dies D8 and the seventh semiconductor die D7 may be inspected (S82).

In embodiments, the wafer W to which the seventh semiconductor dies D7 are bonded may be loaded onto the first stage 72 of the die bonding apparatus 60, and the die bonding apparatus 60 may pick up the eighth semiconductor die D8 separated by a sawing process and may bond it onto the good seventh semiconductor die D7.

Then, the wafer W to which the eighth semiconductor dies D8 are bonded may be loaded onto the stage 20 of the defect inspection apparatus 10 of FIG. 1, and presence or absence of voids at the bonding interfaces of the eighth semiconductor dies D8 and the seventh semiconductor die D7 may be inspected. Through the defect inspection, it may be possible to select good eighth semiconductor dies D8 KGD having no voids.

Hereinafter, a method of manufacturing a semiconductor package using the defect inspection apparatus of FIG. 1 will be described. A case in which the semiconductor package includes a high bandwidth memory (HBM) device will be described. However, it will be understood that the method of manufacturing a semiconductor package in accordance with embodiments is not limited thereto.

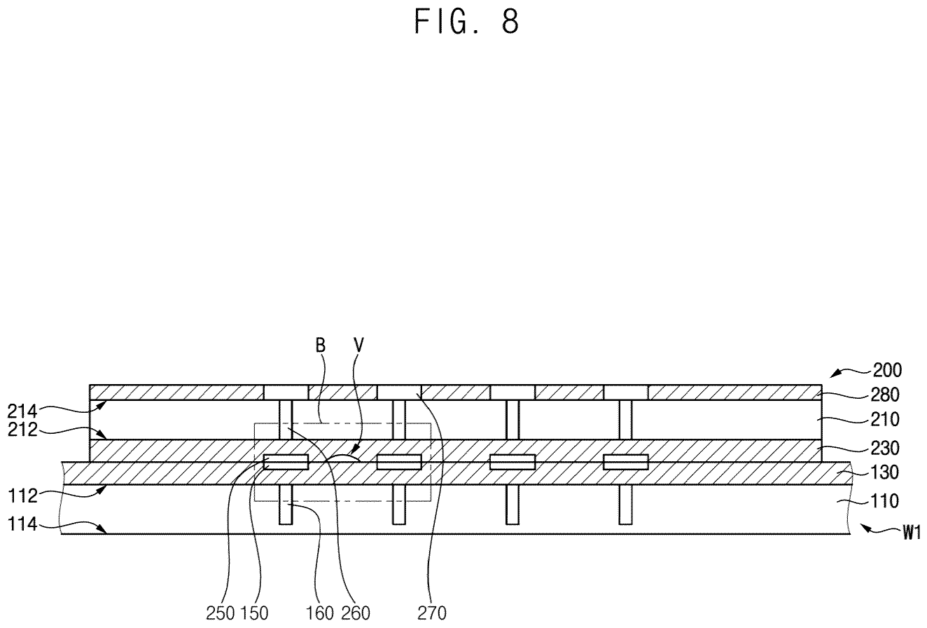

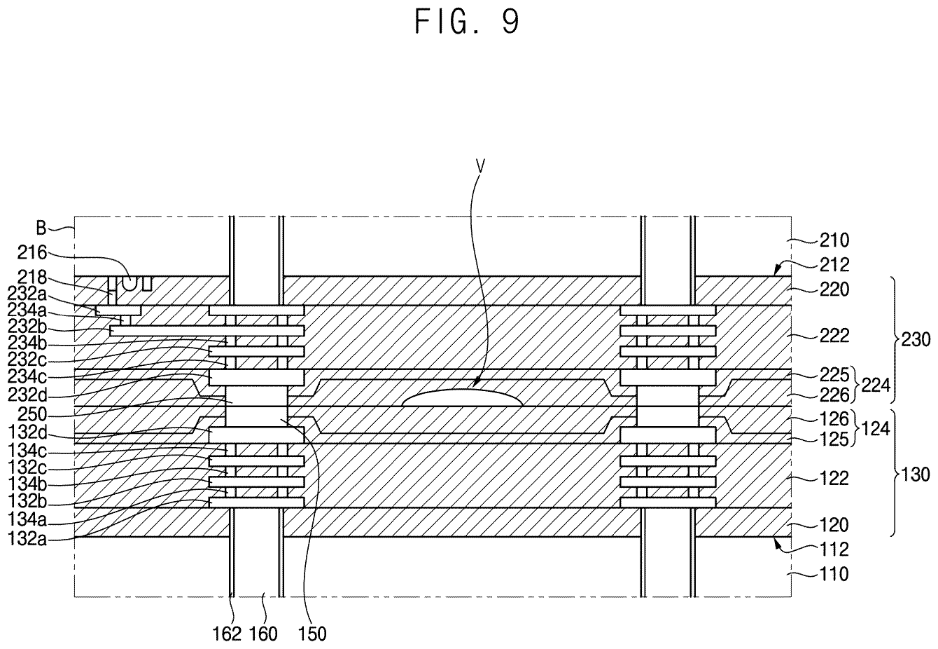

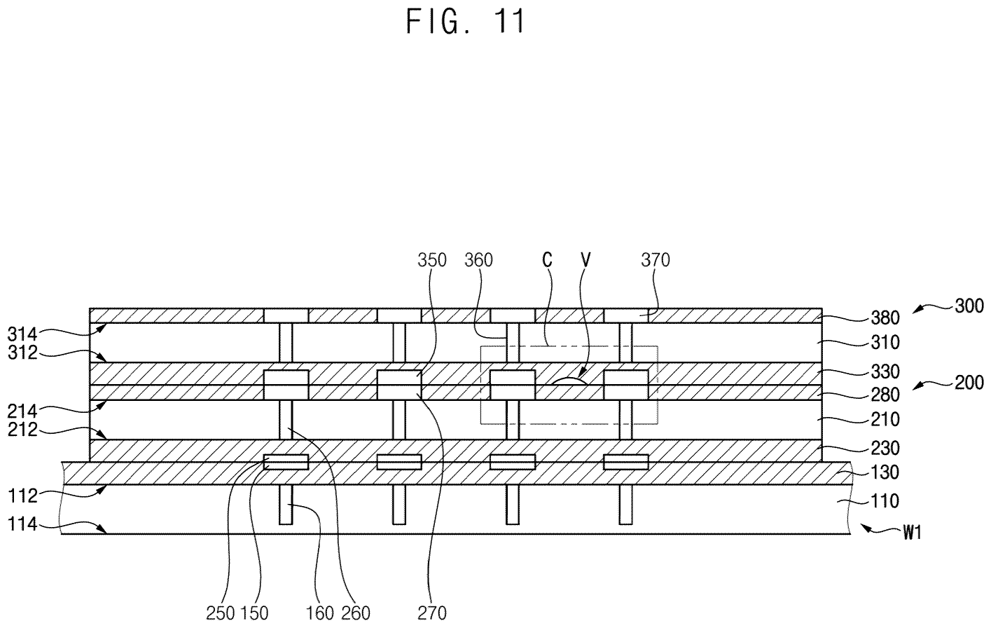

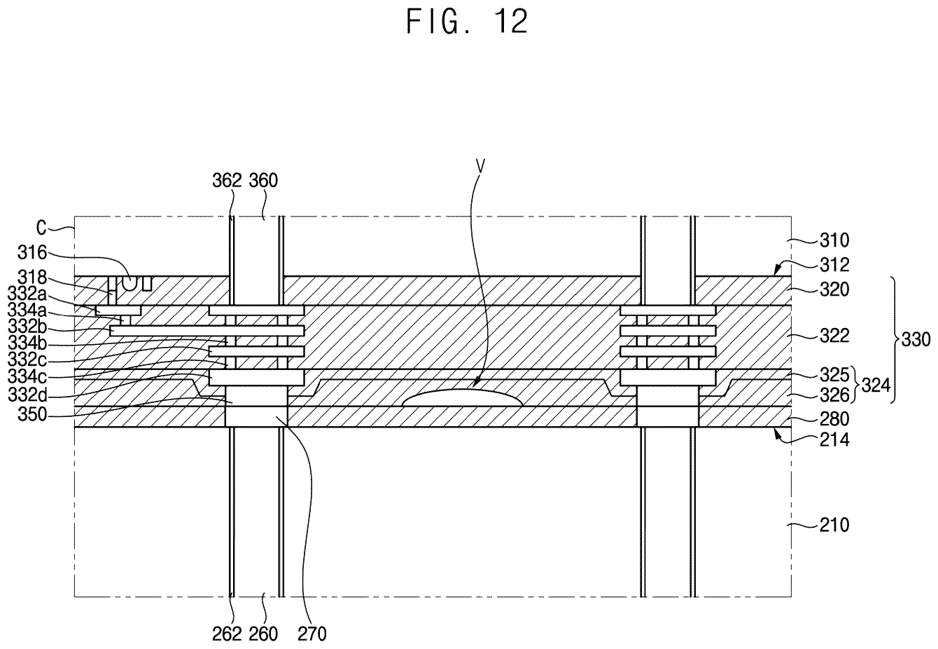

FIGS. 8 to 17 are views illustrating a method of manufacturing a semiconductor package, in accordance with embodiments. FIG. 9 is an enlarged cross-sectional view illustrating a portion ‘B’ in FIG. 8. FIG. 12 is an enlarged cross-sectional view illustrating a portion ‘C’ in FIG. 11.

Referring to FIGS. 8 to 10, first, second semiconductor chips 200 separated by a sawing process may be bonded onto a first wafer W1 (die to wafer hybrid bonding process).

In embodiments, a second wafer in which a plurality of second semiconductor chips (dies) are formed may be prepared, and then, the second wafer may be cut along a scribe lane region to form the second semiconductor chips 200. Then, the second semiconductor chips 200 may be disposed on the first wafer W1 to correspond to die regions of the first wafer W1. The second semiconductor chips 200 may be stacked such that a first surface 212 of a second substrate 210 of each of the second semiconductor chips 200 is directed to the first wafer W1.

As illustrated in FIG. 10, the die bonding apparatus 60 may pick up the second semiconductor chips 200 separated through the sawing process and may bond them to the first wafer W1.

For example, a lower support structure 70 of the die bonding apparatus 60 may include a first stage 72 for holding the first wafer W1, and an upper support structure 80 may include a second stage 82 for holding a second semiconductor chip 200. A bonding head driver 84 may adsorb the second semiconductor chip 200 using the upper support structure 80 as a bonding head, and may move the upper support structure 80 to bond the adsorbed second semiconductor chip 200 onto the first wafer W1. For example, the bonding head driver 84 may move the bonding head in X, Y, and Z directions. Alternatively, the bonding head driver 84 may move the bonding head in the Z direction, and the first stage driver 74 may move the first stage 72 such that the first wafer W1 moves in the X and Y directions and rotates around the center of the first wafer W1.

The die bonding apparatus 60 may perform a thermal compression process at a predetermined temperature (e.g., about 400° C. or less) to attach the second semiconductor chip 200 on a first surface 112 of the first wafer W1.

As illustrated in FIGS. 8 and 9, the first wafer W1 may include a first substrate 110 and a first front insulating layer 130 having first bonding pads 150 on an outer surface thereof. In addition, the first wafer W1 may include first through electrodes 160 provided in the first substrate 110 and electrically connected to the first bonding pads 150, respectively.

The first substrate 110 may have the first surface 112 and a second surface 114 opposite to the first surface 112. The first substrate 110 may include a die region where circuit patterns and cells are formed and a scribe lane region SA surrounding the die region. The first substrate 110 may be separated by being cut along the scribe lane region forming a plurality of die regions of the first wafer W1 by a subsequent dicing process (singulation process).

The first substrate 110 may include silicon, germanium, silicon-germanium, or III-V compounds, e.g., GaP, GaAs, GaSb, etc., for example. In some embodiments, the first substrate 110 may be a silicon-on-insulator (SOI) substrate, or a germanium-on-insulator (GOI) substrate.

The first front insulating layer 130 as an insulation interlayer may be formed on the first surface 112 of the first substrate 110, that is, a front surface. The first front insulating layer 130 may include a plurality of insulating layers 120, 122 and 124 and wirings in the plurality of insulating layers. In addition, the first bonding pad 150 may be provided at an outermost insulating layer of the first front insulating layer 130. For example, the first front insulating layer 130 may include a first interlayer insulating layer 120, a second interlayer insulating layer 122 and a first passivation layer 124.

The first through electrode 160 may vertically penetrate the first interlayer insulating layer 120, and may extend from the first surface 112 of the first substrate 110 to a predetermined depth. The first through electrode 160 may be electrically connected to the first bonding pad 150 through the wirings. A liner layer 162 may be provided on an outer surface of the first through electrode 160. The liner layer may include silicon oxide or carbon-doped silicon oxide. The liner layer 162 may electrically insulate the first through electrode 160 from the first substrate 110 and the first front insulating layer 130.

In embodiments, the second semiconductor chip 200 may include a second substrate 210, a second front insulating layer 230 having a third bonding pad 250 on an outer surface thereof and a second backside insulating layer 280 having a fourth bonding pad 270. Additionally, the second semiconductor chip 200 may include a second through electrode 260 that penetrates the second substrate 210.

The second substrate 210 may have a first surface 212 and a second surface 214 opposite to the first surface 212. The first surface 212 may be an active surface, and the second surface 214 may be an inactive surface. Circuit patterns 216 may be provided on the first surface 212 of the second substrate 210. The first surface 212 may be referred to as a front surface on which circuit patterns are formed, and the second surface 214 may be referred to as a backside surface.

The second front insulating layer 230 as an insulation interlayer may be formed on the first surface 212 of the second substrate 210, that is, the front surface. The second front insulating layer 230 may include a plurality of insulating layers 220, 222 and 224 and wirings in the plurality of insulating layers. In addition, the third bonding pad 250 may be provided at an outermost insulating layer of the second front insulating layer 230. For example, the second front insulating layer 230 may include a first interlayer insulating layer 220, a second interlayer insulating layer 222, and a third passivation layer 224.

The first interlayer insulating layer 220 may be provided on the first surface 212 of the second substrate 210 to cover the circuit patterns 216. The first interlayer insulating layer 220 may be formed to include, for example, silicon oxide or a low-k material. The first interlayer insulating layer 220 may include lower wirings 218 therein.

The second interlayer insulating layer 222 may include a plurality of buffer layers and insulating layers alternately formed with each other. For example, the buffer layer may include silicon nitride, silicon carbon nitride, SiCON, and the like. The insulating layer may include silicon oxide, carbon-doped silicon oxide, silicon carbonitride (SiCN), and the like.

The second interlayer insulating layer 222 may include a plurality of wirings therein. For example, the second interlayer insulating layer 222 may include a metal wiring structure including a plurality of first wirings vertically stacked in the buffer layers and the insulating layers. The plurality of first wirings may include a first metal wiring 232a, a first contact 234a, a second metal wiring 232b, a second contact 234b, a third metal wiring 232c, a third contact 234c and a fourth metal wire 232d. The fourth metal wiring 232d as the uppermost first wiring may be provided on the second interlayer insulating layer 222. The fourth metal wiring 232d may have a thickness greater than a thickness of each of the first to third metal wirings. The third bonding pad 250 may be formed on the fourth metal wiring 232d as the uppermost first wiring.

The third passivation layer 224 may be formed on the second interlayer insulating layer 222, and may expose at least a portion of the third bonding pad 250. The third passivation layer 224 may include a plurality of stacked insulating layers. For example, the third passivation layer 224 may include an organic passivation layer 225 including an oxide layer and an inorganic passivation layer 226 including a nitride layer, which are sequentially stacked. The inorganic passivation layer 226 may include silicon nitride or silicon carbonitride.

The third bonding pad 250 may be provided at an outermost insulating layer of the second front insulating layer 230. The third bonding pad 250 may be exposed through an outer surface of the second front insulating layer 230. Accordingly, the circuit pattern 216 may be electrically connected to the third bonding pad 250 by the lower wirings and the wirings.

The second backside insulating layer 280 serving as a fourth passivation layer may be formed on the second surface 214 of the second substrate 210, and may expose at least a portion of the fourth bonding pad 270. The fourth bonding pad 270 may be disposed on the exposed surface of the second through electrode 260. The second backside insulating layer 280 may include silicon oxide, carbon-doped silicon oxide, silicon carbonitride (SiCN), etc. Accordingly, the third bonding pad 250 and the fourth bonding pad 270 may be electrically connected by the second through electrode 260.

The third bonding pad 350 and the fourth bonding pad 270 and the second through electrode 260 may include the same metal. For example, the metal may include copper (Cu). However, it may not be limited thereto, and may include a material (e.g., gold (Au)) that can be combined by interdiffusion of metals by a high-temperature annealing process.

In embodiments, the second semiconductor chip 200 and the first wafer W1 may be bonded to each other by a hybrid bonding process. That is, the second front surface insulating layer 230 on a front surface of the second semiconductor chip 200, that is, the first surface 212 of the second substrate 210 may be directly bonded to the first front insulating layer 130 on the first substrate 110 of the first wafer W1.

The first bonding pad 150 of the first wafer W1 and the third bonding pad 250 of the second semiconductor chip 200 may contact each other. The front surface of the second semiconductor chip 200 and the front surface of the first wafer W1 may be bonded to be directed to each other. When the first wafer W1 and the second semiconductor chip 200 are bonded to each other by wafer to die bonding, the second front insulating layer 230 and the first front insulating layer 130 may be directly bonded to each other, and the first bonding pad 150 of the wafer W1 and the third bonding pad 250 of the second semiconductor chip 200 may be bonded to each other by Cu—Cu hybrid bonding.

The outermost insulating layers of the first front insulating layer 130 and the second front insulating layer 230 may contact each other to provide a bonding structure having excellent bonding strength. The first front insulating layer 130 and the second front insulating layer 230 may be bonded to each other by a high-temperature annealing process while in contact with each other. At this time, the bonding structure may have a stronger bonding strength by covalent bonding. However, a void V may be formed between the first front insulating layer 130 and the second front insulating layer 230. A defect inspection process for inspecting presence or absence of such void may be performed.

Then, the first wafer W1 to which the second semiconductor chips 200 are bonded may be loaded onto the stage 20 of the defect inspection apparatus 10 of FIG. 1, and presence or absence of voids at bonding interfaces of the second semiconductor chips 200 and the first waver W1 may be inspected. Through the defect inspection, good second semiconductor chips 200 having no voids may be selected.

Referring to FIGS. 11 and 12, processes the same as or similar to the processes described with reference to FIGS. 8 to 10 may be performed to bond third semiconductor chips 300 to the second semiconductor chips 200 on the first wafer W1 (die to wafer hybrid bonding process).

In embodiments, the first wafer W1 to which the second semiconductor chips 200 are bonded may be loaded onto the first stage 72 of the die bonding apparatus 60, and the die bonding apparatus 60 may pick up the third semiconductor chips 300 separated by a sawing process, and may bond them onto the good second semiconductor chips 200.

A third semiconductor chip 300 may be stacked such that a front surface of the third semiconductor chip 300 is directed to the backside surface of a second semiconductor chip 200. Through a thermal compression process, the third semiconductor chip 300 and the second semiconductor chip 200 may be bonded to each other by hybrid bonding. That is, a third front insulating layer 330 on the front surface of the third semiconductor chip 300 may be directly bonded to the second backside insulating layer 280 on the backside surface of the second semiconductor chip 200.

As illustrated in FIG. 12, the third semiconductor chip 300 may include a third substrate 310, a third front insulating layer 330 provided on a front surface 312 of the third substrate 310, and a third backside insulating layer 380 provided on a back surface 314 of the third substrate 310. The third semiconductor chip 300 may further include a third through electrode 360 penetrating the third substrate 310. A fifth bonding pad 350 may be provided at an outermost insulating layer of the third front insulating layer 330. A sixth bonding pad 370 may be provided at the third backside insulating layer 380.

For example, the third front insulating layer 330 may include a first interlayer insulating layer 320, a second interlayer insulating layer 322 and a fifth passivation layer 324.

The first interlayer insulating layer 320 may be provided on the first surface 312 of the third substrate 310 to cover circuit patterns 316. The first interlayer insulating layer 320 may include lower wirings 318 therein.

The second interlayer insulating layer 322 may include a plurality of buffer layers and insulating layers alternately formed with each other. The second interlayer insulating layer 322 may include a plurality of wirings therein.

For example, the second interlayer insulating layer 322 may include a metal wiring structure including a plurality of first wirings vertically stacked in the buffer layers and the insulating layers. The plurality of first wirings may include a first metal wiring 332a, a first contact 334a, a second metal wiring 332b, a second contact 334b, a third metal wiring 332c, a third contact 334c and a fourth metal wiring 332d. The fourth metal wiring 332d as an uppermost first wiring may be provided on the second interlayer insulating layer 322. The fourth metal wiring 332d may have a greater thickness than each of the first to third metal wirings. The fifth bonding pad 350 may be formed on the fourth metal wiring 332d as the uppermost first wiring.

The fifth passivation layer 324 may be formed on the second interlayer insulating layer 322, and may expose at least a portion of the fifth bonding pad 350. For example, the third passivation layer 324 may include an organic passivation layer 325 including an oxide layer and an inorganic passivation layer 326 including a nitride layer, sequentially stacked.

The fifth bonding pad 350 may be provided at an outermost insulating layer of the third front insulating layer 330. The fifth bonding pad 350 may be exposed through an outer surface of the third front insulating layer 330. Accordingly, the circuit pattern 316 may be electrically connected to the fifth bonding pad 350 by the lower wirings and the wirings.

The front surface 312 of the third substrate 310 may be directed to the backside surface 214 of the second substrate 210. The third front insulating layer 330 and the second backside insulating layer 280 may be directly bonded to each other. Accordingly, the fourth bonding pad 270 and the fifth bonding pad 350 are bonded to each other between the second semiconductor chip 200 and the third semiconductor chip 300 by Cu—Cu hybrid bonding (pad to pad direct bonding).

The outermost insulating layers of the second backside insulating layer 280 and the third front insulating layer 230 may contact each other to provide a bonding structure including an insulating material providing excellent bonding strength. The second backside insulating layer 280 and the third front insulating layer 230 may be bonded to each other by a high-temperature annealing process while in contact with each other. At this time, the bonding structure may have a stronger bonding strength by covalent bonding. However, a void V may be formed between the second backside insulating layer 280 and the third front insulating layer 330. A defect inspection process for inspecting presence or absence of such void may be performed.

Then, the first wafer W1 to which the third semiconductor chips 300 are bonded may be loaded onto the stage 20 of the defect inspection apparatus 10 of FIG. 1, and presence or absence of voids at bonding interfaces of the third semiconductor chips 300 and the second semiconductor chips 200 may be inspected. Through the defect inspection, good third semiconductor chips 300 having no voids may be selected.

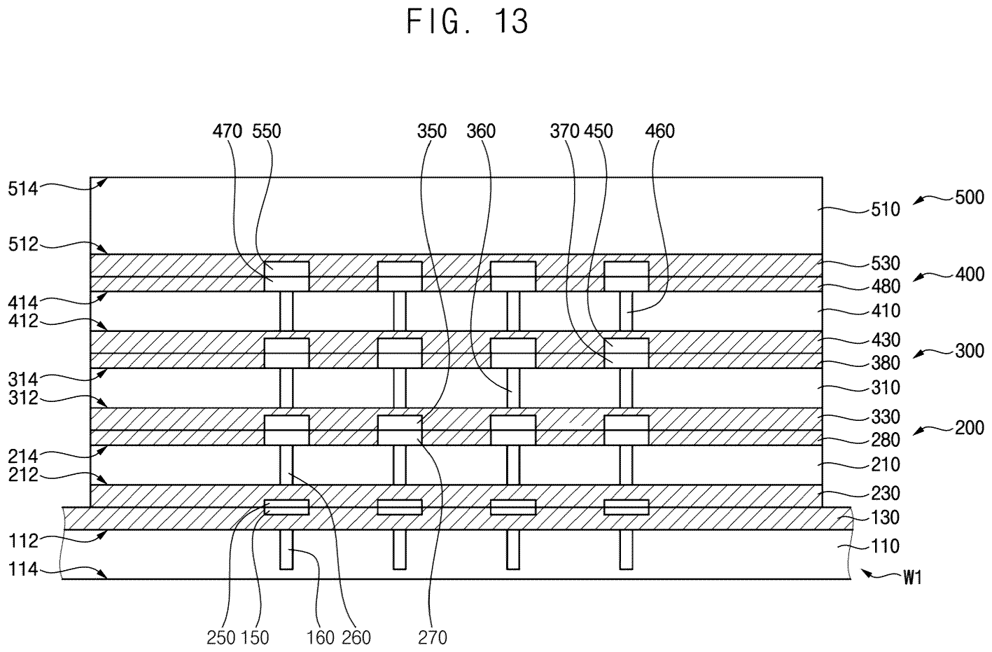

Referring to FIG. 13, processes the same as or similar to the processes described with reference to FIGS. 11 and 12 may be performed to sequentially bonding fourth semiconductor chips 400 and fifth semiconductor chips 500 to the third semiconductor chips 300 on the first wafer W1 (die to wafer hybrid bonding process), and after each bonding process, a defect inspection process may be performed.

In embodiments, the first wafer W1 to which the third semiconductor chips 300 are bonded may be loaded onto the first stage 72 of the die bonding apparatus 60, and the die bonding apparatus 60 may pick up the fourth semiconductor chips 400 separated by a sawing process, and may bond them onto the good third semiconductor chips 300.

A fourth semiconductor chip 400 may be stacked such that a front surface of the fourth semiconductor chip 400 is directed to the backside surface of the third semiconductor chip 300. Through a thermal compression process, the fourth semiconductor chip 400 and the third semiconductor chip 300 may be bonded to each other by hybrid bonding. That is, a fourth front insulating layer 430 on the front surface of the fourth semiconductor chip 400 may be directly bonded to the third backside insulating layer 380 on the backside surface of the third semiconductor chip 300.

A front surface 412 of the fourth substrate 410 may be directed to the backside surface 314 of the third substrate 310. The fourth front insulating layer 430 and the third backside insulating layer 380 may be directly bonded to each other. Accordingly, the sixth bonding pad 370 and a seventh bonding pad 450 between the third semiconductor chip 300 and the fourth semiconductor chip 400 may be bonded to each other by Cu—Cu Hybrid Bonding (pad to pad direct bonding).

The outermost insulating layers of the third backside insulating layer 380 and the fourth front insulating layer 430 may contact each other to provide a bonding structure including an insulating material providing excellent bonding strength. The third backside insulating layer 380 and the fourth front insulating layer 430 may be bonded to each other by a high-temperature annealing process while in contact with each other. At this time, the bonding structure may have a stronger bonding strength by covalent bonding. However, a void may be formed between the third backside insulating layer 380 and the fourth front insulating layer 430. A defect inspection process for inspecting presence or absence of such void may be performed.

Then, the first wafer W1 to which the fourth semiconductor chips 400 are bonded may be loaded onto the stage 20 of the defect inspection apparatus 10 of FIG. 1, and presence or absence of voids at bonding interfaces of the fourth semiconductor chips 400 and the third second semiconductor chips 300 may be inspected. Through the defect inspection, it may be possible to select good fourth semiconductor chips 400 having no voids.

Then, the first wafer W1 to which the fourth semiconductor chips 400 are bonded may be loaded onto the first stage 72 of the die bonding apparatus 60, and the die bonding apparatus 60 may pick up the fifth semiconductor chips 500 separated by a sawing process, and may bond them on the good fourth semiconductor chips 400.

The fifth semiconductor chip 500 may be stacked such that a front surface of the fifth semiconductor chip 500 is directed to a backside surface of the fourth semiconductor chip 400. Through a thermal compression process, the fifth semiconductor chip 500 and the fourth semiconductor chip 400 may be bonded to each other by hybrid bonding. That is, a fifth front insulating layer 530 on the front surface of the fifth semiconductor chip 500 may be directly bonded to the fourth backside insulating layer 480 on the backside surface of the fourth semiconductor chip 400. A void may be formed between the third backside insulating layer 380 and the fourth front insulating layer 430. A defect inspection process for inspecting the presence or absence of such void may be performed.

Then, the first wafer W1 to which the fifth semiconductor chips 500 are bonded may be loaded onto the stage 20 of the defect inspection apparatus 10 of FIG. 1, and presence or absence of voids at bonding interfaces of the fifth semiconductor chips 500 may be inspected. Through the defect inspection, good fifth semiconductor chips 500 having no voids may be selected.

It will be appreciated that the number of stacked semiconductor chips is not limited thereto. For example, 4, 8 or 12 semiconductor chips may be sequentially stacked on the fifth semiconductor chip 500.

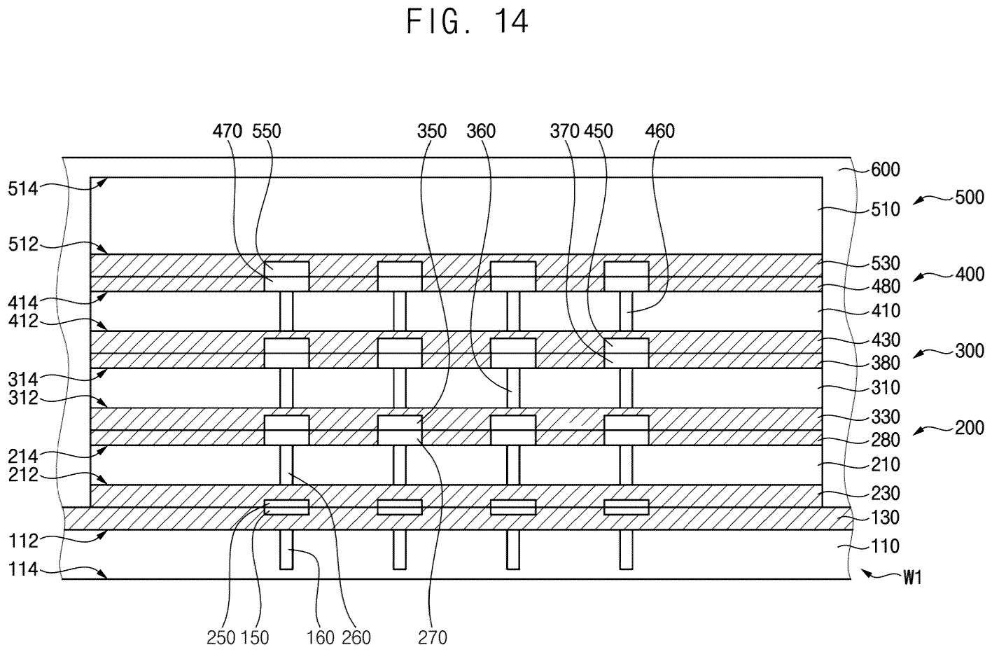

Referring to FIG. 14, a sealing member 600 may be formed to fill between the stacked structures of the second, third, fourth, and fifth semiconductor chips 200, 300, 400, and 500.

In embodiments, the sealing member 600 may be formed to cover the second semiconductor chip 200, the third second semiconductor chip 300, the fourth second semiconductor chip 400, and the fifth semiconductor chip 500 on the first wafer W1. The sealing member 600 may be formed by a dispensing process or a spin coating process. For example, the sealing member 600 may include a thermosetting resin or the like.

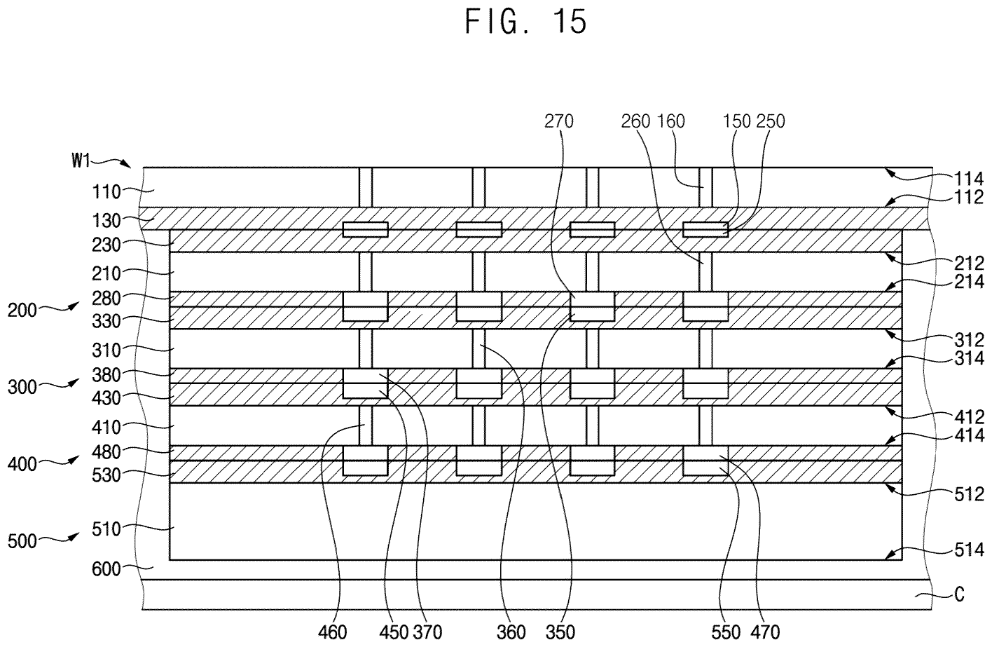

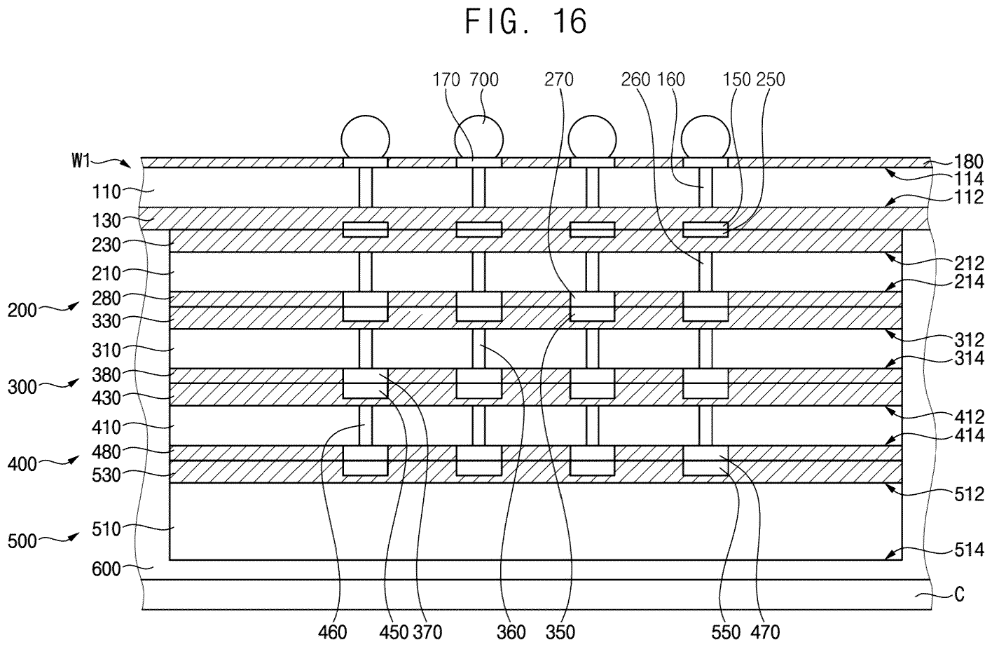

Referring to FIGS. 15 and 16, a first backside insulating layer 180 having a second bonding pad 170 electrically connected to the first through electrode 160 may be formed on the second surface 214 of the first substrate 110 of the first wafer W1, and a solder bump 700 as a conductive connection member may be formed on the second bonding pad 170.

As illustrated in FIG. 15, the backside surface of the first substrate 110, that is, the second surface 114 may be polished using a substrate support system (WSS). After the structure of FIG. 14 is turned over and the sealing member 600 is attached on a carrier substrate C using an adhesive film, the second surface 114 of the first substrate 110 may be partially removed until a portion of the first through electrode 160 is exposed.

As illustrated in FIG. 16, the first backside insulating layer 180 having the second bonding pad 170 electrically connected to the first through electrode 160 may be formed on the second surface 114 of the first substrate 110, an opening may be formed in the first backside insulating layer 180 to expose the first through electrode 160, and a plating process may be performed to form the second bonding pad 170.

Then, the solder bumps 700 may be formed on the second bonding pads 170.

In particular, a seed layer may be formed on the second bonding pad 170 of the first backside insulating layer 180, and a photoresist pattern having an opening exposing a seed layer region may be formed on the first backside insulating layer 180.

Then, after filling the opening of the photoresist pattern with a conductive material, the photoresist pattern may be removed and a reflow process may be performed to form the solder bump 700. For example, the conductive material may be formed on the seed layer by a plating process. Alternatively, the solder bumps may be formed by a screen printing method, a deposition method, or the like.

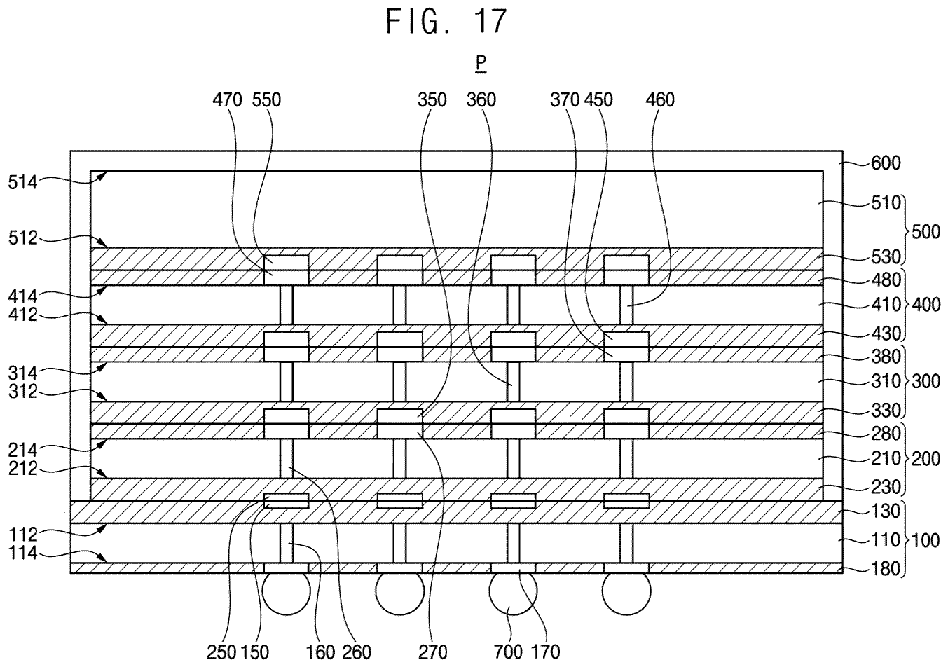

Referring to FIG. 17, the first wafer W1 and the sealing member 600 may be cut along the scribe lane region SA to form a semiconductor package P.

The semiconductor package P may include the stacked first to fifth semiconductor chips 100, 200, 300, 400 and 500. A plurality of semiconductor chips 100, 200, 300, 400 and 500 may be vertically stacked. In this embodiment, the first to fifth semiconductor chips 100, 200, 300, 400 and 500 may be substantially the same as or similar to each other.

In this embodiment, a semiconductor package as a multi-chip package is illustrated as including four stacked semiconductor chips 200, 300, 400 and 500 on the first semiconductor chip 100. However, it may not be limited thereto, and for example, the semiconductor package may include 8, 12 or 16 semiconductor chips stacked on the first semiconductor chip 100.

Each of the first to fifth semiconductor chips 100, 200, 300, 400 and 500 may include an integrated circuit chip completed by performing semiconductor manufacturing processes. Each of the semiconductor chips may include, for example, a memory chip or a logic chip. The semiconductor package P may include a memory device. The memory device may include a high bandwidth memory (HBM) device. In this case, the first semiconductor chip 100 may be provided as a buffer die, and the second to fifth semiconductor chips 200, 300, 400 and 500 may be provided as semiconductor memory dies.

The semiconductor package may include semiconductor devices such as logic devices or memory devices. The semiconductor package may include logic devices such as central processing units (CPUs), main processing units (MPUs), or application processors (APs), or the like, and volatile memory devices such as dynamic random-access memory (DRAM) devices, HBM devices, or non-volatile memory devices such as flash memory devices, phase-change random-access memory (PRAM) devices, magnetoresistive random-access memory (MRAM) devices, resistive random-access memory (ReRAM) devices, or the like.

The foregoing is illustrative of embodiments and is not to be construed as limiting thereof. Although a few embodiments have been described, those skilled in the art will readily appreciate that many modifications are possible in or to the embodiments without materially departing from the novel teachings and advantages of the disclosure. Accordingly, all such modifications are intended to be included within the scope of the embodiments as defined in or represented by the claims.

1. A method of manufacturing a semiconductor package, the method comprising:
providing a first semiconductor die on a stage;
bonding a second semiconductor die to the first semiconductor die to each other;
applying heat to a surface of the second semiconductor die, which is opposite to a bonding interface of the first semiconductor die and the second semiconductor die; and
measuring a temperature change on the surface of the second semiconductor die to which the heat is applied to inspect a state of the bonding interface.

2. The method of claim 1, wherein the applying the heat to the surface of the second semiconductor die comprises irradiating a light forming a line-shaped radiation area extending in a first direction on the surface of the second semiconductor die.

3. The method of claim 2, wherein the irradiating the light comprises irradiating the light from a laser or a halogen lamp onto the surface of the second semiconductor die.

4. The method of claim 2, further comprising:
moving the stage in at least one direction when the heat is applied to the surface of the second semiconductor die.

5. The method of claim 4, further comprising:
adjusting a moving speed of the stage.

6. The method of claim 4, wherein the moving the stage in the at least one direction comprises reciprocally moving the stage within a preset distance based on a specific position.

7. The method of claim 1, wherein the measuring the temperature change on the surface of the second semiconductor die to which the heat is applied comprises detecting an infrared ray emitted from the surface of the second semiconductor die using a thermal imaging camera to generate a thermal image.

8. The method of claim 1, wherein the inspecting the state of the bonding interface comprises determining whether a void exists between the first semiconductor die and the second semiconductor die by the measuring the temperature change.

9. The method of claim 1, wherein the bonding the second semiconductor die to the first semiconductor die is performed by hybrid bonding.

10. The method of claim 9, wherein the first semiconductor die comprises a first passivation layer, and the second semiconductor die comprises a second passivation layer bonded to the first passivation layer, and
wherein the state of the bonding interface comprises whether a void is present between the first passivation layer and the second passivation layer.

11. A method of manufacturing a semiconductor package, the method comprising:
placing a buffer die on a stage;
sequentially bonding a plurality of semiconductor dies on the buffer die; and
inspecting a state of a bonding interface of each of the bonded semiconductor dies when each of the semiconductor dies is bonded to another of the bonded semiconductor dies,
wherein inspecting the state of the bonding interface comprises:
applying heat to a surface of each of the bonded semiconductor dies, which is opposite to the bonding interface thereof; and
detecting an infrared ray emitted from the surface of each of the bonded semiconductor dies to which the heat is applied to determine the state of the bonding interface.

12. The semiconductor package of claim 11, wherein the applying the heat to the surface of each of the bonded semiconductor dies comprises irradiating a light forming a line-shaped irradiation area extending in a first direction to the surface of each of the bonded semiconductor dies.

13. The method of claim 12, wherein the irradiating the light is performed using a laser or a halogen lamp.

14. The method of claim 12, further comprising:
moving the stage in at least one direction when the heat is applied to the surface of each of the bonded semiconductor dies.

15. The method of claim 14, wherein the moving the stage in the at least one direction comprises reciprocally moving the stage within a preset distance based on a specific position.

16. The method of claim 11, wherein the detecting the infrared ray emitted from the surface of each of the bonded semiconductor dies to which the heat is applied comprises detecting the infrared ray using a thermal imaging camera to generate a thermal image.

17. The method of claim 11, wherein each of the plurality of semiconductor dies comprises:
a substrate;
an insulating layer on a first surface of the substrate;
a first bonding pad at the insulating layer;
a first passivation layer, on the insulating layer, exposing at least a portion of the first bonding pad;
a second bonding pad on a second surface of the substrate; and
a second passivation layer, on the second surface of the substrate, exposing at least a portion of the second bonding pad.

18. The method of claim 17, wherein each of the plurality of semiconductor dies further comprises a through electrode penetrating the substrate and electrically connected to at least one of the first bonding pad and the second bonding pad.

19. The method of claim 17, wherein the first bonding pad and the second bonding pad are directly bonded to each other, and
wherein the first passivation layer and the second passivation layer are directly bonded to each other.

20. The method of claim 11, further comprising:
forming a sealing member on the buffer die and the bonded semiconductor dies.

21-30. (canceled)
